(19) United States
(12) Patent Application Publication
(10) Pub. No.: US 2021/0254206 A1
(43) Pub. Date: Aug. 19, 2021

(54) BALL AND VALVE SEAT FOR FUEL INJECTOR, AND METHOD FOR COATING THE SAME

(71) Applicant: HYUNDAI KEFICO CORPORATION, Gunpo, Gyeonggi-do (KR)

(72) Inventors: Heon Joon Park, Gunpo, Gyeonggi-do (KR); Hae Hyuk Jung, Jeju, Jeju-do (KR); Sung Chul Cha, Seoul (KR); Won Ki Chung, Seoul (KR)

(21) Appl. No.: 17/275,055

(22) PCT Filed: Aug. 19, 2019
(86) PCT No.: PCT/KR2019/010500

§ 371 Date: Mar. 10, 2021

(30) Foreign Application Priority Data
Sep. 14, 2018 (KR) 10-2018-0110200

(51) Int. Cl. C23C 14/06; F02M 61/18; C23C 14/28; C23C 16/30; C23C 16/50; C23C 14/02; C23C 16/02

(52) U.S. Cl. CPC C23C 14/0641; F02M 61/1886; C23C 14/28; C23C 16/30; F02M 2200/9046; C23C 14/022; C23C 14/025; C23C 16/0281; F02M 2200/9038; C23C 16/50

(57) ABSTRACT

A ball and a valve seat for a fuel injector, and a method for coating the same are provided to form a Ta—C:H—SiO functional layer having a low frictional characteristic as the outermost layer to reduce a frictional coefficient. A Mo-based material is applied to a bonding layer and a supporting layer for bonding and supporting the Ta—C:H—SiO functional layer is applied to a base material to improve heat resistance. Accordingly, only pure ionic Mo particles are deposited to form the bonding layer and the supporting layer, thereby increasing an adhesive force and a bonding force to improve durability.

### BACKGROUND

### Field of the Disclosure

The present disclosure relates to a ball and a valve seat for a fuel injector, and a method for coating the same, and more particularly, a coating structure of a ball and a valve seat on which a coating material is stacked and a method for coating the same, which reduce frictional resistance, and increases coating hardness and durability life.

### Description of the Related Art

A fuel injector for a vehicle is an important part for supplying fuel to an engine in a timely manner according to the stroke of the engine. In this regard, since a ball and a valve seat decrease in size, sliding parts among parts of fuel injectors, but are exposed to higher and repetitive loads and stresses, a phenomenon in which lifespan is reduced by thermal impact, wear, and the like are likely to occur.

As a method for improving the wear resistance of such sliding parts, Korean Patent Application Publication No. 10-2014-0038084 discloses a configuration relating to a coating material which forms a Cr or Ti bonding layer on a base material of a sliding part, forms a CrN or WC supporting layer on the surface of the bonding layer, and forms a SiO-DLC functional layer on the surface of the supporting layer, thereby improving wear resistance and heat resistance of the sliding parts.

However, according to the structure disclosed in the prior art, the SiO-DLC functional layer is provided on the outermost layer to improve friction resistance performance, however, Cr, Ti, or W-based material may not secure sufficient heat resistance performance and interlayer bonding force, thereby being unsuitable to be applied in a high temperature environment and a high vibration environment such as a ball and a valve seat.

Meanwhile, Japanese Patent Application Publication No. 1994-25826 discloses a configuration of a sliding member to which a Mo-based material is applied instead of a Cr, Ti or W-based material as a coating material. The document discloses a physical vapor deposition method of an ion plating method for forming a Mo film by depositing Mo ions evaporated using a high energy beam on a base material in connection with a method for depositing a Mo-based material.

However, in the deposition method disclosed in the prior art, non-uniformity of the particles is caused, and the particles are deposited by the phenomenon in which non-ionic particles having a relatively large diameter are deposited on the base material together with the Mo ion particles evaporated from the Mo target by a high energy beam, thereby degrading the roughness of the coating film and degrading the bonding force to the base material, and thus, there is a high possibility of significantly reducing the durability of the coating film entirely.

### SUMMARY

The present disclosure is intended to solve the aforementioned problems of the related art, and an object of the present disclosure is to provide a ball and a valve seat for a fuel injector, and a method for coating the same, which form a Ta—C:H—SiO functional layer having a low friction characteristic as an outermost layer to reduce a frictional coefficient, and apply a Mo-based material to a bonding layer and a supporting layer for bonding and supporting the Ta—C:H—SiO functional layer to the base material, thereby improving heat resistance, and are configured so that only pure ionic Mo particles are deposited to form the bonding layer and the supporting layer, thereby increasing an adhesive force and a bonding force to improve durability.

Accordingly, the present disclosure provides the ball and the valve seat for the fuel injector on which a coating material having a multi-layer structure is stacked on the surface of a base material, the coating material may include a Mo bonding layer which is stacked on the surface of the base material, a MoN supporting layer which is stacked on the outer surface of the Mo bonding layer, and a Ta—C:H—SiO functional layer which is stacked on the outer surface of the MoN supporting layer, and the Mo bonding layer and the MoN supporting layer are stacked by a physical vapor deposition method, and the Ta—C:H—SiO functional layer is stacked by a chemical vapor deposition method.

Further, the Mo bonding layer is formed by depositing Mo ions on the base material, the Mo ions being evaporated by radiating laser to a Mo target under the vacuum atmosphere to induce an arc. The MoN supporting layer is formed by depositing MoN particles on the outer surface of the Mo bonding layer, the MoN particles being formed by reacting the Mo ions separated from the Mo target through the laser radiation in a state where the Mo bonding layer is completely stacked, and N ions separated from N2 gas injected as activated gas.

Additionally, non-ionic particles other than the Mo ions are generated by radiating the laser to the Mo target, and the non-ionic particles are collected through an electromagnetic filter, thereby preventing the non-ionic particles from being stacked on the base material or the Mo bonding layer. The chemical vapor deposition method includes a PACVD method using carbonized gas and Hexamethyl Disiloxane (HMDSO) gas. Prior to stacking the Mo bonding layer, Ar ions in a plasma state collide with the surface of the base material to clean the surface of the base material.

Meanwhile, the present disclosure may include, as the coating method which stacks a coating material having a multi-layer structure on the surface of a base material of the ball and the valve seat for the fuel injector, forming a Mo bonding layer which stacks a Mo bonding layer on the outer circumferential surface of the base material by a physical vapor deposition method, forming a MoN supporting layer which stacks a MoN supporting layer on the outer surface of the Mo bonding layer by a physical vapor deposition method, and forming a Ta—C:H—SiO functional layer which stacks the Ta—C:H—SiO functional layer on the outer surface of the MoN supporting layer by a chemical vapor deposition method.

The forming of the Mo bonding layer includes generating Mo ions which generates Mo ions evaporated by radiating laser to a Mo target under the vacuum atmosphere to induce an arc, moving the Mo ions which moves the Mo ions to the surface of the base material, and depositing the Mo ions which deposits the moved Mo ions on the surface of the base material.

Further, the forming of the MoN supporting layer includes forming MoN particles which forms MoN particles by reacting the Mo ions separated from the Mo target through the laser radiation in a state where the Mo bonding layer is completely stacked, and N ions separated from N2 gas injected as activated gas, and depositing the MoN particles which deposits the MoN particles on the outer surface of the Mo bonding layer.

Additionally, non-ionic particles other than the Mo ions are generated in the generating of the Mo ions, and the non-ionic particles are collected through an electromagnetic filter, thereby preventing the non-ionic particles from being stacked on the base material or the Mo bonding layer. Further, the chemical vapor deposition method includes a PACVD method using carbonized gas and Hexamethyl Disiloxane (HMDSO) gas.

The method may further include forming vacuum which keeps the internal atmosphere of a reaction chamber as a vacuum state, in a state where the ball and the valve seat are disposed inside the reaction chamber, forming plasma which forms a plasma state where Ar ions are generated by injecting Ar gas into the reaction chamber, and increasing a temperature of the reaction chamber, and cleaning which cleans the surface of the base material by colliding the Ar ions with the surface of the base material of the ball and the valve seat.

The ball and valve seat for the fuel injector, and the method for coating the same according to the present disclosure may form the Ta—C:H—SiO functional layer having a low friction characteristic as the outermost layer to reduce the frictional coefficient, and apply the Mo-based material to the bonding layer and the supporting layer for bonding and supporting the Ta—C:H—SiO functional layer to the base material, thereby improving heat resistance, and are configured so that only the pure ionic Mo particles are deposited to form the bonding layer and the supporting layer, thereby increasing the adhesive force and the bonding force to improve durability.

### BRIEF DESCRIPTION OF THE DRAWINGS

FIG. 1 is a partially enlarged diagram of a fuel injector having a ball and a valve seat according to an embodiment the present disclosure;

FIG. 2 is a diagram schematically illustrating the cross sections of the ball and the valve seat on which a coating material deposited according to an embodiment of the present disclosure is stacked;

FIG. 3 is a photograph of a scanning electron microscope (SEM) of the coating material deposited according to an embodiment of the present disclosure;

FIG. 4 is a diagram schematically illustrating a coating apparatus for forming the coating material according to an embodiment the present disclosure; and

FIG. 5 is a flowchart for explaining a coating method according to an embodiment of the present disclosure.

### DETAILED DESCRIPTION

Hereinafter, a configuration of a ball and a valve seat for a fuel injector and a method for coating the same according to the present disclosure will be described in detail with reference to the accompanying drawings.

Various changes and various embodiments may be made in the present disclosure, such that specific embodiments are illustrated in the drawings and described in detail in the specification. It should be understood, however, that it is not intended to limit the present disclosure to the particular disclosed forms, but includes all modifications, equivalents, and alternatives falling within the sprit and technical scope of the present disclosure.

In describing the present disclosure, the terms “first,” “second,” and the like may be used to illustrate various components, but the components should not be limited by the terms. The terms are used to differentiate one element from another. For example, a first component may be referred to as a second component, and similarly, the second component may also be referred to as the first component without departing from the scope of the present disclosure. The terms “and/or” includes a combination of a plurality of related listed items or any of a plurality of related listed items.

When a component is referred to as being “connected” or “coupled” to another component, it may be directly connected or coupled to another component, but it may be understood that other components may be present therebetween. On the other hand, when a component is referred to as being “directly connected” or “directly coupled” to another component, it may be understood that there are no other components therebetween.

The terminology used in the present application is merely for the purpose of describing particular embodiments, and is not intended to limit the present disclosure. The singular forms used herein may include plural forms, unless the phrases clearly indicate the opposite. In the present application, it may be understood that the term “comprising”, “having”, or the like specifies the presence of the characteristic, integer, step, operation, component, part, or a combination thereof described in the specification, and does not exclude the presence or addition possibility of one or more other characteristics, integers, steps, operations, components, parts or combinations thereof in advance.

Unless defined otherwise, all terms including technical terms and scientific terms used herein have the same meaning as commonly understood by those skilled in the art to which the present disclosure pertains. Terms, such as those defined in commonly used dictionaries are interpreted to have a meaning consistent with the meaning on the context of the related technology, and are not interpreted in an ideal or very formal sense unless defined clearly in the present application.

Further, the following embodiments are provided to more fully describe the present disclosure to those skilled in the art, and the shape and size of the elements in the drawings may be exaggerated for clarity.

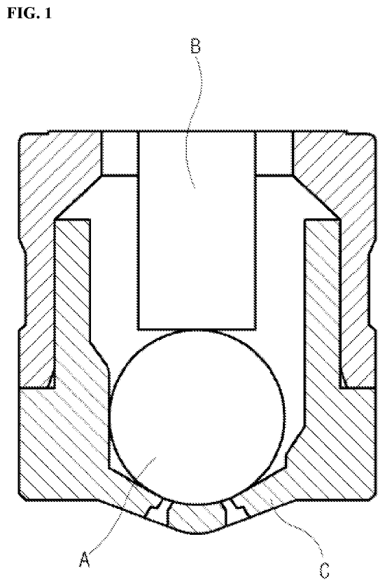

FIG. 1 is a partially enlarged diagram of a fuel injector to which a ball and a valve seat according to the present disclosure are applied. Referring to FIG. 1, the fuel injector includes a housing which accommodates a needle therein, a valve seat (C) formed at the bottom of the housing, and a ball (A) disposed between the valve seat (C) and the needle (B). The valve seat (C) has a valve seat surface on which the ball (A) is seated, and the valve seat (C) includes a nozzle which penetrates in a fuel injection direction.

The needle (B) opens and closes the nozzle formed on the valve seat (C) while moving the ball (A) vertically by the operations of a magnetic coil and a return spring which are not illustrated. FIG. 1 illustrates the ball (A) having a spherical shape, but the present disclosure is not limited thereto, and additionally, valve bodies having various shapes are applicable without limitation and they all are regarded as falling within the scope of the present disclosure. For convenience, the following description will be given based on an embodiment of the ball (A) having the spherical shape. Since a fuel injector, particularly, a direct injection type fuel injector directly injects fuel into a cylinder, the ball (A) and valve seat (C) are exposed to a high-temperature and high-pressure state, and there is a high possibility of causing a phenomenon such as nozzle clogging due to combustion by-products such as carbon monoxide and soot.

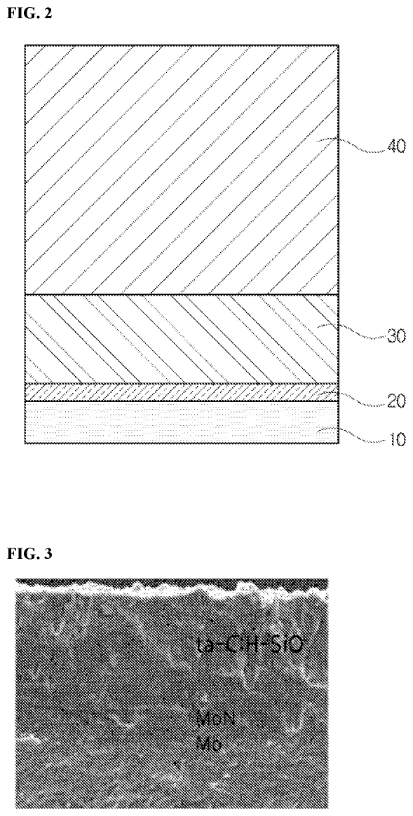

As described above, since the ball (A) and the valve seat (C) are exposed to the high-temperature and high-pressure state, and may be broken more easily by a substantial frictional resistance generated by the combustion by-products, the present disclosure is configured so that the coating material having a multi-layer structure may be stacked on a base material 10 of the ball (A) and the valve seat (C), thereby reducing the frictional resistance, increasing durability, and increasing heat resistance, as illustrated in FIG. 2.

Referring to FIGS. 2 and 3, the coating material according to an embodiment of the present disclosure includes a Mo bonding layer 20 stacked on the surface of the base material 10 of the ball and the valve seat, a MoN supporting layer 30 stacked on the outer surface of the Mo bonding layer 20, and a Ta—C:H—SiO functional layer 40 stacked on the outer surface of the MoN supporting layer 30.

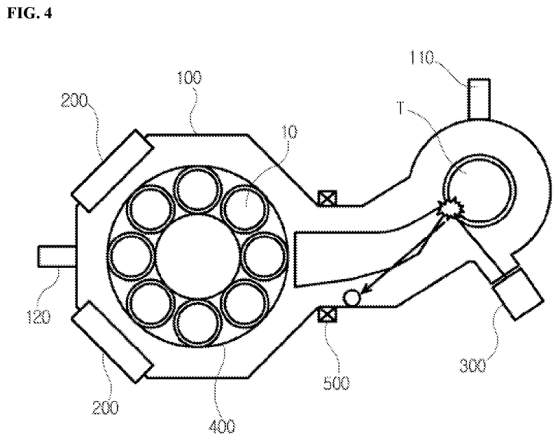

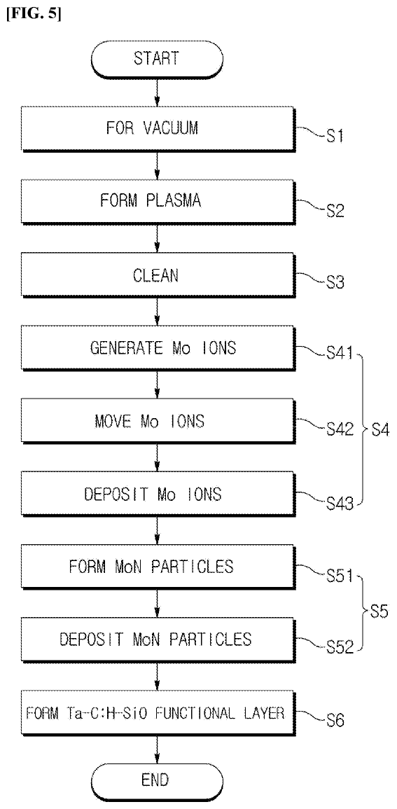

The Mo bonding layer 20 and the MoN supporting layer 30 are stacked by a physical vapor deposition method, preferably a Filtered Laser Arc Deposition (FLAD) method, and the Ta—C:H—SiO functional layer 40 is stacked by a chemical vapor deposition method, preferably, a Plasma-Assisted Chemical Vapor Deposition (PACVD) method using carbonized gas and Hexamethyl Disiloxane (HMDSO) gas. The detailed steps of stacking the Mo bonding layer 20, the MoN supporting layer 30, and the Ta—C:H—SiO functional layer 40 will be described later with reference to FIGS. 4 and 5.

The Mo bonding layer 20 bonds the base material 10 and the MoN supporting layer 30 of the ball and the valve seat, and may be formed to have a thickness in the range of about 0.01 to 0.5 μm, preferably 0.05 μm, but is not limited thereto. If the thickness of the Mo bonding layer 20 is less than about 0.01 μm, the bonding force may be reduced, thereby decreasing durability. Additionally, if the thickness of the Mo bonding layer 20 is greater than about 0.5 μm, a coating time takes 5 hours or more, and t hardness balance may be lost due to a thick film within the coating material, thereby reducing durability.

The MoN supporting layer 30 supports the Mo bonding layer 20 and the Ta—C:H—SiO functional layer 40, may be formed to have a thickness in the range of about 0.1 to 5 μm, preferably, 0.2 μm, but is not limited thereto. If the thickness of the MoN supporting layer 30 is less than about 0.1 μm, the interlayer hardness balance may be lost due to the lack of the thickness of the supporting layer causing a reduction in the durability due to the loss of the interlayer hardness balance, a local loss in the thickness, and wear marks (wear starting point operation). Further, if the thickness of the MoN supporting layer 30 is greater than about 5 μm, the coating time increases (e.g., 5 hours or more) and a columnar structure (e.g., brittle texture) is formed by adversely affecting the Ta—C:H—SiO coating, thereby increasing the interlayer residual stress.

The SiO including tetrahedral hydrogenated amorphous carbon (Ta—C:H—SiO) functional layer 40 corresponds to an outermost layer of the coating material according to the present disclosure, and provides as a functional layer having low friction, wear resistance, and heat resistance. The thickness of the Ta—C:H—SiO functional layer 40 may be about 0.1 to 10 μm, preferably, 0.8 μm, but is not limited thereto.

If the thickness of the Ta—C:H—SiO functional layer 40 is less than about 0.1 μm, durability is reduced by an increase in wear and an increase in a frictional coefficient due to the lack of the thickness of the functional layer, and if the thickness of the Ta—C:H—SiO functional layer 40 is greater than about 10 μm, the coating time increases (e.g., 5 hours or more), the cost increases, and the interlayer residual stress increases.

Meanwhile, the Ta—C:H—SiO functional layer 40 according to the present disclosure is configured to have a component ratio of carbon (C) of 50 to 85% by weight, hydrogen (H) of 1 to 4% by weight, silicon (Si) of 1 to 25% by weight, and oxygen (O) of 1 to 25% by weight based on 100% by weight. This is because there may cause problems in that the hardness and lubricity of the Ta—C:H—SiO functional layer 40 become insufficient when the carbon (C) has the content of less than 50% by weight, and the hardness of the Ta—C:H—SiO functional layer 40 becomes excessive when the carbon (C) has a content greater than 85% by weight, thereby having brittleness and resulting in the lack of heat resistance and seizure resistance.

Further, the frictional coefficient of the Ta—C:H—SiO functional layer 40 may increase and wear resistance may become insufficient when the hydrogen (H) has the content of less than 1% by weight, and the Ta—C:H—SiO functional layer 40 lacks lubricity, heat resistance, and seizure resistance when the hydrogen (H) has the content is greater than 40% by weight. Additionally, the frictional coefficient of the Ta—C:H—SiO functional layer 40 may increase and heat resistance and moisture resistance may become insufficient when the silicon (Si) has the content of less than 1% by weight, and the hardness and lubricity of the Ta—C:H—SiO functional layer 40 becomes insufficient when the silicon (Si) has the content greater than 25% by weight.

Further, the seizure resistance of the Ta—C:H—SiO functional layer 40 may become insufficient, the transparency (aesthetics) may be inhibited, and scratch resistance may become insufficient when the oxygen (O) has the content of less than 1% by weight, and the hardness and lubricity of the Ta—C:H—SiO functional layer 40 may become insufficient when the oxygen (O) has the content greater than 25% by weight.

The present disclosure applies the Mo material as the bonding layer and the supporting layer, and applies the Ta—C:H—SiO as the functional layer of the outermost layer as described above, thereby simultaneously securing sufficient heat resistance, wear resistance, and durability as the coating material of the ball and the valve seat for the fuel injector as compared to when Cr, Ti, or W-based material is applied as before.

Hereinafter, a coating method and a coating apparatus for the ball and the valve seat for the fuel injector according to the present disclosure will be described with reference to FIGS. 4 and 5. First, a coating material may be formed on the base material 10 of the ball and the valve seat for a vehicle according to the present disclosure using the coating apparatus illustrated in FIG. 4.

Referring to FIG. 4, the illustrated coating apparatus may include a reaction chamber 100, a Mo target (T) fixed inside the reaction chamber 100, a gas inlet 110 for injecting process gas into the reaction chamber 100, a gas outlet 120 which discharges residual process gas, a bias electrode 200, a laser generator 300 which radiates laser to the Mo target (T), a turn table 400 which supports the base material 10 of the ball and the valve seat, an electromagnetic filter 500 which collects non-ionic particles separated from the Mo target (T), and the like.

The reaction chamber 100 may separate the inner space from the outer space to form predetermined coating conditions (e.g., temperature and pressure) therein. A pair of bias electrodes 200 may a predetermined bias voltage difference to accelerate Ar ions to collide with the surface of the base material to clean the surface of the base material 10 as described later. The bias electrode 200 is connected to a bias power supply not illustrated, and a bias voltage between the pair of bias electrodes 200 is maintained in a range of 200 to 400V as described later.

The laser generator 300 radiates the laser to the Mo target (T) to induce an arc, and evaporates the surface of the Mo target (T) to generate gaseous Mo ions from the Mo target (T). In other words, the present disclosure uses the laser generator to deposit Mo ions and MoN particles through a physical vapor deposition method, preferably, a laser arc vapor deposition method, as described later. The laser generator 300 is applicable to the present disclosure without limitation as long as it has an output of the level capable of generating gaseous Mo ions from the Mo target (T).

Meanwhile, the electromagnetic filter 500 collects the non-ionic Mo particles other than the Mo ions separated from the Mo target (T) by the laser generator 300, and implements a Filtered Laser Arc Deposition (FLAD) with electromagnetic filtering in addition to the aforementioned laser arc vapor deposition method (Laser Arc Deposition). In other words, when an arc is generated by radiating the laser to the Mo target (T) through the laser generator 300, a number of non-ionic Mo particles having a relatively large and non-uniform diameter are formed in addition to the Mo ions in the evaporated gas state.

There is a high possibility of causing problems in that when such non-ionic Mo particles are deposited on the base material 10 together with the Mo ions, the surface roughness of the deposition layer is degraded due to the non-uniformity of the deposition surface, and an adhesive force of the deposition layer is reduced. Accordingly, to ensure that only the pure Mo ions separated from the Mo target (T) are deposited on the base material, the present disclosure forms the Mo bonding layer and the MoN supporting layer through the FLAD deposition method which allows the non-ionic Mo particles to be collected through the electromagnetic filter 500.

As illustrated, the electromagnetic filter 500 is disposed on the moving path of the Mo ions between the Mo target (T) and a turn table 400. Meanwhile, although not illustrated, a constant temperature device may be provided inside the reaction chamber 100 adjacent to the turn table 400, thereby increasing the internal temperature of the reaction chamber 100 up to about 600° C.

Hereinafter, a method for coating the ball and the valve seat for the fuel injector according to the present disclosure will be described step by step with reference to FIG. 5. First, the base material 10 of the ball and the valve seat is disposed on the turn table 400 inside the reaction chamber 100, and the internal atmosphere of the reaction chamber 100 is formed in a vacuum state and kept as it is (S1).

As the process gas 300, Ar gas is supplied through the gas inlet 110, and the temperature is increased using the constant temperature device to form a plasma state in which Ar ions are formed inside the reaction chamber 100 (S2) Preferably, the interior of the reaction chamber 100 is maintained at 80° C. using the constant temperature device.

The coating method performs cleaning (S3) which cleans the surface of the base material of the ball and the valve seat by applying a bias voltage to the bias electrode 200, and accelerating Ar ions to collide with the surface of the base material of the ball and the valve seat. The cleaning (S3) preferentially performs an etching process for removing an oxygen layer and impurities formed naturally on the surface of the base material of the ball and the valve seat, and is performed for the purpose of increasing the adhesive force between the coating material and the base material.

Further, in this case, it is preferable to maintain the bias voltage in the range of 200 to 400 V. This is because when the bias voltage is less than 200 V, the acceleration voltage of the Ar ion reduces and the hardness of the coating material is reduced, and when the bias voltage is greater than 400 V, the lattice arrangement may become irregular, thereby reducing an adhesive force. After cleaning the base material of the ball and the valve seat with the Ar ions, the coating method performs forming a Mo bonding layer (S4) which forms a Mo bonding layer by stacking Mo ions on the surface of the base material through a physical vapor deposition method, preferably, the aforementioned FLAD method.

More specifically, the forming of the Mo bonding layer (S4) may be classified into generating Mo ions (S41) which are evaporated by radiating laser to a Mo target under the vacuum atmosphere formed in the reaction chamber 100 to induce an arc, moving the Mo ions (S42) which moves the generated Mo ions to the surface of the base material disposed on the turn table 400, and depositing the Mo ions (S43) which deposits the moved Mo ions on the surface of the base material.

Further, the coating method performs forming a MoN supporting layer (S5) which stacks a MoN supporting layer on the outer surface of the Mo bonding layer, which is formed in the forming of the Mo bonding layer (S4), through a physical vapor deposition method, preferably, a laser arc vapor deposition method. More specifically, the forming of the MoN supporting layer (S5) may be classified into forming MoN particles (S51) which forms MoN particles by reacting Mo ions separated from the Mo target through laser radiation in a state where the Mo bonding layer 20 is completely stacked, and N ions separated from N2 gas which is injected as activated gas through the gas inlet 110, and depositing the MoN particles (S52) which deposits the formed MoN particles on the outer surface of the Mo bonding layer 20.

In particular, the non-ionic particles generated in the generating of the Mo ions (S41) are collected through the electromagnetic filter 500 as described above, thereby preventing the non-ionic particles from being stacked on the base material or the Mo bonding layer. Next, the coating method performs forming a Ta—C:H—SiO functional layer (S6) which stacks the Ta—C:H—SiO functional layer 40 on the outer surface of the MoN supporting layer 30 by a chemical vapor deposition method, preferably, a PACVD method.

In particular, the Ta—C:H—SiO functional layer 40 is formed by injecting carbonized gas (C_{X}H_{Y}) and Hexamethyl Disiloxane (HMDSO) gas, which are process gases, through the gas inlet 110 into the reaction chamber 100, to complete the formation of the coating material according to the present disclosure.

The Ta—C:H—SiO functional layer 40 deposits a coating film on the surface thereof by generating plasma in the vacuum state, and forms a carbon film having a diamond-like structure on the surface thereof, using carbon-based gas, and the present disclosure is configured to form the Ta—C:H—SiO functional layer 40 through a method for injecting the HMDSO gas while injecting the carbonized gas into the reaction chamber 100 to form the Ta—C:H—SiO functional layer 40.

Particularly, the carbonized gas is preferably methane (CH₄) gas and ethane gas (C₂H₆), for example, but the present disclosure is not limited thereto. Hereinafter, the results of a durability performance evaluation comparison and a physical property evaluation comparison of the embodiment manufactured by applying the coating method according to the present disclosure and Comparative Examples manufactured according to the related art will be described.

### EMBODIMENT

The surface of the base material was cleaned by making a plasma state using Ar gas in a state where the interior of the reaction chamber 100 is vacuum, activating the surface of the base material 10 made of a SUS440C stainless iron material by heating the interior of the reaction chamber 100 at 80° C., and then applying a bias voltage of 300 V to cause Ar ions to collide with the surface thereof.

Thereafter, the Mo bonding layer was stacked in a thickness of 0.05 μm by depositing the Mo ions evaporated through the FLAD method on the surface of the base material. Further, the MoN supporting layer 30 was coated in a thickness of 0.2 μm by injecting N₂, which is process gas, into the reaction chamber 100 to react the N₂ with the Mo ions evaporated from the Mo target (non-ionic Mo particles were collected by the electromagnetic filter). Thereafter, the Ta—C:H—SiO functional layer 40 was stacked in a thickness of 0.8 μm by injecting the carbonized gas and the HMDSO gas into the reaction chamber.

### Comparative Example 1

Unlike an embodiment according to the present disclosure, it is characterized by not forming the coating material on the base material of the ball and the valve seat. The base material of the ball and the valve seat was made of SUS440C stainless iron as in an embodiment.

### Comparative Example 2

The coating material having the same thickness as in an embodiment was formed on the SUS440C stainless iron base material of the same ball and valve seat, but Cr was used instead of Mo to form a Cr bonding layer on the surface of the base material of the ball and the valve seat, a CrN supporting layer was formed on the outer circumferential surface of the Cr bonding layer, and then a SiO-DLC functional layer was formed on the surface of the CrN supporting layer through a method for injecting the HMDSO gas while injecting the carbonized gas into the reaction chamber 100.

### Comparative Example 3

In the same manner as an embodiment of the present disclosure, the coating material including the Mo bonding layer and the MoN supporting layer was stacked on the SUS440C stainless iron base material of the ball and the valve seat, but unlike an embodiment of the present disclosure, the Mo bonding layer and the MoN supporting layer were deposited through the existing general physical vapor deposition (PVD) method (e.g., a separate electromagnetic filter is not applied) to form the SiO-DLC layer as the outermost layer.

### Durability Performance Evaluation Experiment

To perform the durability performance evaluation, a dry-run test was performed. This durability test was an experiment for evaluating the durability of each coating material in a short period of time, and an embodiment and Comparative Examples 1 to 3 were conducted under the following test conditions in the same manner. The test gas was air or nitrogen, the supply pressure was 5 bar, and the test temperature was performed at room temperature; and Peak & Hold (PHID, 1.2 A & 0.6 A current control method) was used as a driver stage, the supply voltage was 14.0 V, a pulse period was 5.0 ms, a pulse width was 2.5 ms, and an operating time was 30 minutes or more.

As a determination criterion, whether there was damage such as peeling of the surface of the coating material was visually confirmed, and the coating thickness was evaluated. The average value of the coating thicknesses of two places of 0° and 180° of the product and the thickness difference of the coating materials of two places were measured. The thickness was measured by using a calotester.

TABLE 1

| | | Comparative | Comparative | Comparative |
|---|---|---|---|---|
| | Embodiment | Example 1 | Example 2 | Example 3 |
| | Mo/MoN/Ta- | SUS440C (no | Cr/CrN/SiO- | Mo/MoN/SiO- |
| Items | C:H-SiO | coating) | DLC | DLC |
| Thickness (μm) | 1.0 | — | 2.0 | 2.0 |
| Coating time | <4 h | — | <6 | <6 h |
| Coating process | FLAD & | — | PVD & | PVD & |
| | PACVD | | PACVD | PACVD |
| Durability | Thickness: 0% | Wear marks | Thickness: 27% | Thickness: 19% |
| performance | Visually | (large) | Visually loss: | Visually loss: |
| evaluation results | loss: no | | wear marks | wear marks |
| (Dry-run test) | wear marks | | found | found |

According to Table 1, it was confirmed, as the durability performance experiment result, that the ball and the valve seat to which the coating material according to an embodiment of the present disclosure was applied had a 0% loss in a thickness of the coating material, and had no wear marks. On the other hand, in Comparative Example 2, it was confirmed that the thickness of the coating material was lost by 27%, and some wear marks were found.

Further, in Comparative Example 3, it was confirmed that the thickness of the coating material was lost by 19%, and some wear marks were found. As a result, as a result of testing the durability performance for the coating material of the ball and the valve seat, it was confirmed that an embodiment of the present disclosure had a low loss rate and a good durability performance of the coating material even though it took less coating time as compared to Comparative Examples.

### Physical Property Evaluation

To evaluate the physical properties of the coating material, the physical property evaluation was performed. To derive the frictional coefficient, a Plate on disk experiment was conducted by using 10 N, 0.1 m/s, 2 km, and SUS440C pin. For the hardness measurement, a micro indenter (0.05 N, 0.7 μm indenting depth) was used. For the adhesive force measurement, a scratch tester and a rockwell C tester (HF1: high bonding force, HF5: low bonding force) were used.

TABLE 2

| | | Comparative | Comparative | Comparative |
|---|---|---|---|---|
| | Embodiment | Example 1 | Example 2 | Example 3 |
| | Mo/MoN/Ta- | SUS440C (no | Cr/CrN/SiO- | Mo/MoN/SiO- |
| Items | C:H-SiO | coating) | DLC | DLC |
| Hardness (HV) | 4642 | 772 | 2173 | 2281 |
| | (45.52 GPa) | (7.32 GPa) | (30.63 GPa) | (21.66 GPa) |
| Heat resistance | 600° C. | — | 400° C. | 400° C. |
| temperature | | | | |
| Roughness Ra | 0.022 | 0.2 | 0.043 | 0.040 |
| (μm) | | | | |
| Friction | 0.05 | 0.45 | 0.13 | 0.11 |
| coefficient Dry | | | | |
| Friction | 0.025 | 0.22 | 0.06 | 0.05 |
| coefficient oil | | | | |
| Adhesive force | HF 138 N | — | HF 1-231 N | HF 1-233 N |

As expressed in Table 2,

It was confirmed that in an embodiment of the present disclosure, the hardness value is improved compared to Comparative Examples, and the frictional coefficient was also measured relatively low to reduce frictional resistance. Further, the adhesive force of the coating material according to an embodiment of the present disclosure was 38N, which was evaluated to be superior to the adhesive force of 33N in other Comparative Examples, particularly, in Comparative Example 3, and it is analyzed that this is because the surface roughness of an embodiment deposited according to the FLAD method of the present application may be kept very low.

What is claimed is:

1. A ball and a valve seat for a fuel injector, as the ball and the valve seat for the fuel injector on which a coating material having a multi-layer structure is stacked on the surface of a base material, wherein the coating material comprises:
a Mo bonding layer stacked on the surface of the base material;
a MoN supporting layer stacked on the outer surface of the Mo bonding layer; and
a Ta—C:H—SiO functional layer stacked on the outer surface of the MoN supporting layer,
wherein the Mo bonding layer and the MoN supporting layer are stacked by a physical vapor deposition method, and the Ta—C:H—SiO functional layer is stacked by a chemical vapor deposition method.

2. The ball and the valve seat for the fuel injector of claim 1, wherein the Mo bonding layer is formed by depositing Mo ions on the base material, the Mo ions being evaporated by radiating laser to a Mo target under the vacuum atmosphere to induce an arc.

3. The ball and the valve seat for the fuel injector of claim 2, wherein the MoN supporting layer is formed by depositing MoN particles on the outer surface of the Mo bonding layer, the MoN particles being formed by reacting the Mo ions separated from the Mo target through the laser radiation in a state where the Mo bonding layer is completely stacked, and N ions separated from N2 gas injected as activated gas.

4. The ball and the valve seat for the fuel injector of claim 3, wherein non-ionic particles other than the Mo ions are generated by radiating the laser to the Mo target, and wherein the non-ionic particles are collected through an electromagnetic filter to prevent the non-ionic particles from being stacked on the base material or the Mo bonding layer.

5. The ball and the valve seat for the fuel injector of claim 1, wherein the chemical vapor deposition method includes a PACVD method using carbonized gas and Hexamethyl Disiloxane (HMDSO) gas.

6. The ball and the valve seat for the fuel injector of claim 1, wherein before the Mo bonding layer is stacked, Ar ions in a plasma state collide with the surface of the base material to clean the surface of the base material.

7. A method for coating a ball and a valve seat for a fuel injector, the method comprising:
forming a Mo bonding layer which stacks a Mo bonding layer on an outer circumferential surface of a base material of the ball by a physical vapor deposition method;
forming a MoN supporting layer which stacks a MoN supporting layer on an outer surface of the Mo bonding layer by a physical vapor deposition method; and
forming a Ta—C:H—SiO functional layer which stacks a Ta—C:H—SiO functional layer on the outer surface of the MoN supporting layer by a chemical vapor deposition method.

8. The method of claim 7, wherein the forming of the Mo bonding layer includes:
generating Mo ions which generates Mo ions evaporated by radiating laser to a Mo target under the vacuum atmosphere to induce an arc;
moving the Mo ions which moves the Mo ions to the surface of the base material; and
depositing the Mo ions which deposits the moved Mo ions on the surface of the base material.

9. The method of claim 8, wherein the forming of the MoN supporting layer includes:
forming MoN particles which forms MoN particles by reacting the Mo ions separated from the Mo target through the laser radiation in a state where the Mo bonding layer is completely stacked, and N ions separated from N2 gas injected as activated gas; and
depositing the MoN particles which deposits the MoN particles on the outer surface of the Mo bonding layer.

10. The method of claim 9, wherein non-ionic particles other than the Mo ions are generated in the generating of the Mo ions, and wherein the non-ionic particles are collected through an electromagnetic filter to prevent the non-ionic particles from being stacked on the base material or the Mo bonding layer.

11. The method of claim 7, wherein the chemical vapor deposition method includes a PACVD method using carbonized gas and Hexamethyl Disiloxane (HMDSO) gas.

12. The method of claim 7, further comprising:
forming vacuum which maintains the internal atmosphere of a reaction chamber as a vacuum state, in a state where the ball and the valve seat are disposed inside the reaction chamber;
forming plasma which forms a plasma state where Ar ions are generated by injecting Ar gas into the reaction chamber, and increasing a temperature of the reaction chamber; and
cleaning which cleans the surface of the base material by colliding the Ar ions with the surface of the base material of the ball and the valve seat.
